(19) United States
(12) Patent Application Publication
(10) Pub. No.: US 2013/0321029 A1
(43) Pub. Date: Dec. 5, 2013

(54) INPUT DECISION CIRCUIT

(71) Applicant: Fuji Electric Co., Ltd., Kawasaki-shi (JP)

(72) Inventors: Yuya ABE, Matsumoto-city (JP); Takanori KOHAMA, Matsumoto-city (JP)

(73) Assignee: FUJI ELECTRIC CO., LTD., Kawasaki-shi (JP)

(21) Appl. No.: 13/896,299

(22) Filed: May 16, 2013

(30) Foreign Application Priority Data
May 18, 2012 (JP) 2012-114999

(51) Int. Cl. H03K 5/153

(52) U.S. Cl. CPC H03K 5/153
USPC 327/72

(57) ABSTRACT

An input decision circuit includes a comparator outputting either one of a high voltage or a low voltage on the basis of the result of a comparison between a reference voltage and an input voltage, a base voltage source acting as a base common to the reference voltage and the input voltage, a constant current source supplying a constant current to a constant current path from a DC power supply to the base voltage source, and a resistor inserted in the constant current path. A constant voltage is produced across the resistor for the reference voltage with the electric potential of the base voltage source acting as a base. This provides an input decision circuit in which a threshold voltage is hard to shift even when the driving voltage of the comparator or the electric potential of the ground acting as the base voltage source is varied.

### BACKGROUND OF THE INVENTION

1. Field of the Invention

The present invention relates to an input decision circuit which is provided so that a stable comparator output can be obtained.

2. Background Art

Previously, for a switching circuit which is simple, inexpensive and provided with a hysteresis characteristic, a switching circuit as follows has been proposed. The switching circuit includes a first resistor, second resistor and third resistor connected in series between one end and the other end of a DC power supply, a load and a switching device connected in series between the node between the first resistor and the second resistor and the node between the third resistor and the DC power supply, and a comparator circuit using a voltage applied across the third resistor as a reference voltage and switching an output between a high voltage (hereinafter referred to as a Hi) and a low voltage (hereinafter referred to as a Low) according to the difference between an input voltage and the reference voltage, and switches the switching device with the output of the comparator circuit (see JP-A-2000-59192, for example).

Moreover, when the voltage of a signal with many noises is compared with a threshold voltage, the voltage of the signal crossing the threshold voltage sometimes causes the output of a comparator to frequently change between Hi and Low. For avoiding this, a hysteresis comparator provided with a hysteresis characteristic between an input and an output is also known, by which a stable output signal can be obtained.

FIG. 7 is a circuit diagram schematically showing a related input decision circuit having a plurality of grounds. The input decision circuit 40 shown in FIG. 7 includes a power supply VDD, a first ground 1 (hereinafter simply referred to as a ground 1 or a GND 1), a second ground 2 (hereinafter simply referred to as a ground 2 or a GND 2), resistors R1, R2 and R3 connected in series between the power supply VDD and the ground 1, an electronic control unit 9 (hereinafter simply referred to as an ECU 9) outputting control signals such as ignition timing control signals of sparkplugs of an automobile engine and a hysteresis comparator circuit (hereinafter simply referred to as a comparator) 44 using an operational amplifier for a principal part.

The explanation “a plurality of grounds” given in the foregoing means grounds generally provided in an electronic circuit for a vehicle such as an automobile, for example. In an electronic circuit for a vehicle such as an automobile, a battery is used as a power supply VDD for driving a comparator on condition that the power supply voltage fluctuates and one end of the battery is conductively joined to a metal body as one ground and, along with this, is also conductively joined to an engine as the other ground. Namely, the circuit has resistance between the ground 1 and the ground 2, which makes the electric potentials of the grounds not always equal to each other in some positions. This is referred to as “a plurality of grounds” for convenience of explanation.

The voltage between the power supply VDD and the ground 1 is divided by the resistors R1, R2 and R3 into two reference voltages RefH and RefL. Namely, at a connection point J1 of the resistor R1 and the resistor R2, the reference voltage RefH for turning-on (ON) is produced with the ground 1 as a base. The reference voltage RefH becomes a threshold voltage Von (see FIG. 8A) that switches a voltage VOUT at an output terminal 47 (hereinafter simply referred to as an output VOUT 47) of the comparator 44 from Low to Hi. Moreover, at a connection point J2 of the resistor R2 and the resistor R3, the reference voltage RefL for turning-off (OFF) is produced with the ground as a base. The reference voltage RefL becomes a threshold voltage Voff (see FIG. 8A) that switches the output VOUT 47 from Hi to Low. The ECU 9 produces an input voltage VIN with the ground 1 as a base.

To the three input terminals of the comparator 44, with the two reference voltages RefH and RefL being applied to two of the three input terminals with the ground 1 as the base, the input voltage VIN is inputted to the rest input terminal with the ground 1 as the base common to the three inputted voltages. Moreover, the comparator 44 is driven by the power supply VDD with the ground 2 as the base to output the output VOUT 47. The input decision circuit 40 outputs the output VOUT 47 by bringing it to be switched to either Hi or Low according to the result of the comparison of the input voltage VIN with two reference voltages RefH and RefL. Namely, when the input voltage VIN is higher than the reference voltage RefH for ON, the comparator 44 outputs the output VOUT 47 by bringing it to be Hi. Conversely, when the input voltage VIN is lower than the reference voltage RefL for OFF, the comparator 44 outputs the output VOUT 47 by bringing it to be Low.

FIGS. 8A and 8B are waveform diagrams showing relations among the reference voltages, an input voltage and an output voltage in the related input decision circuit. In FIG. 8A, the case is shown in which the electric potential at the ground 1 is equal to the electric potential at the ground 2. At the left end of FIG. 8A, the output VOUT 47 of the comparator 44 in the input decision circuit 40 is Low. Here, when the input voltage VIN becomes higher than the reference voltage RefH as a result of the comparison made by the comparator 44 between the input voltage VIN and the reference voltage RefH, as is shown at the operating point 81 in FIG. 8A, a Hi signal is outputted. Conversely, when the input voltage VIN is lower than the reference voltage RefH, the output VOUT 47 of the comparator 44 is continuously kept at Low as it is.

Moreover, as is shown at the operating points 81 and 82 in FIG. 8A, a specified hysteresis width is provided between the threshold voltage Von for switching the output VOUT 47 of the comparator 44 from Low to Hi and the threshold voltage Voff for switching the output VOUT 47 in reverse to the foregoing. Due to the presence of the hysteresis width, by a variation in the input voltage VIN to the extent that the input voltage VIN exceeds the threshold voltages Von and Voff which are determined to be a little hard to exceed, the output VOUT 47 is switched from Low to Hi, or vice versa. Namely, when the output VOUT 47 is switched from Low to Hi, the input voltage VIN increases to the extent that the input voltage VIN exceeds the reference voltage RefH for ON determined at the high threshold voltage Von. Conversely, when the output VOUT 47 is switched from Hi to Low, the input voltage VIN decreases to the extent that the input voltage VIN is below the reference voltage RefL for OFF determined at the low threshold voltage Voff.

As noted previously, JP-A-2000-59192 shows an example of related art.

However, when a potential difference is produced between the ground 1 and the ground 2 in the input decision circuit 40 explained with reference to FIG. 7, the electric potential of the power supply VDD based on the electric potential of the ground 2 varies with respect to the electric potential of the ground 1. This, in the input decision circuit 40 operated with the electric potential of the ground 2 as the base, results in change in the two reference voltages RefH and RefL produced on the basis of the ground 1. Moreover, the comparator 44, carrying out an input decision by the threshold voltages Von and Voff on the basis of the electric potential of the ground 1, causes the result of the input decision of the output VOUT 47 based on the ground 2 to be varied. Thus, the related input decision circuit 40 has a problem in that when a potential difference is produced between the ground 1 and the ground 2, both of the threshold voltages Von and Voff are shifted on the ON side and the OFF side.

In FIG. 8B, the waveform of an output is shown when the electric potential of the ground 1 is higher than the electric potential of the ground 2 in the related input decision circuit 40. When the electric potential of the ground 1 is raised from the electric potential shown in a solid line to the electric potential shown in a broken line with respect to the electric potential of the ground 2, the level of the input voltage VIN based on the ground 1 is raised up to VIN′. At this time, when each of the levels of the two reference voltages RefH and RefL is raised from the level shown in a solid line to such a higher level with an ideal width of deviation equal to others as is shown in a coarse broken line, there are no shifts toward the ON side and the OFF side at operating points 83 and 84, at which the input voltage VIN′ crosses the threshold voltages Von and Voff, respectively. The two reference voltages RefH and RefL, however, being produced by dividing the voltage of the power supply VDD with resistors, usually cause the voltage increase in each of the reference voltages RefH and RefL to be smaller than the voltage increase in the ground 1. This, as is shown in FIG. 8B, results in shifts at operating points 85 and 86, at which the input voltage VIN′ crosses the threshold voltages Von and Voff, respectively, toward the ON side and the OFF side.

The problem is the same in the case in which the electric potential of the power supply VDD varies with respect to the ground 1. That is, the variation in the voltage between the power supply VDD and the ground 1 causes the variations in the reference voltages RefH and RefL produced by dividing the voltage between the power supply VDD and the ground 1 with resistors. This also causes the threshold voltages Von and Voff, which are based on the reference voltages RefH and RefL, respectively, to be shifted. In other words, in the case in which the voltage between the power supply VDD and the ground 1 varies, like in the case in which a potential difference is produced between the ground 1 and the ground 2, the threshold voltages Von and Voff are shifted to vary the result of the input decision in the output VVOUT 47 of the comparator 47.

Accordingly, it is an object of the invention to provide an input decision circuit in which threshold voltages become hard to shift in a specified range even in the case in which any one of a potential variation in a base voltage source with respect to a reference voltage, a potential variation in the base voltage source with respect to an input voltage, a variation in a driving voltage of the comparator and a potential variation in a base voltage source for driving the comparator occurs, to make it possible to decide the level of an input voltage more exactly.

### SUMMARY OF THE INVENTION

For achieving the object, in a first form of the invention, an input decision circuit comprises a comparator that outputs one of a high voltage (Hi) or a low voltage (Low) on the basis of the result of a comparison between a reference voltage and an input voltage. The input decision circuit further comprises a base voltage source that acts as a base common to the reference voltage and the input voltage, a constant current source that supplies a constant current to a constant current path formed between a DC power supply and the base voltage source, and a resistor inserted in the constant current path. A constant voltage produced across the resistor is used for the reference voltage with the electric potential of the base voltage source as a base.

According to the above-described constitution, the reference voltage obtained from the resistor inserted in the constant current path formed between a DC power supply and the base voltage source is constant with respect to the base voltage source. The reference voltage and the input voltage are based on the base voltage source common thereto. Therefore, even in the case when the electric potential of the base voltage source or the driving voltage of the comparator is varied, the potential difference between the input voltage and the reference voltage is kept constant. Moreover, since a threshold voltage that is an operating reference of the comparator is based on the constant reference voltage, threshold voltages become hard to shift both on the ON side and on the OFF side. As a result, the input decision circuit is capable of carrying out a more exact decision on the level of the input voltage with respect to the threshold voltage.

In a second form of the invention, the input decision circuit according to the first form of the invention includes a first constant current source that makes a constant current flow in a first constant current path, a second constant current source that makes a constant current flow in a second constant current path, a switching device inserted in the second constant current path, and a third constant current path from the joining point of the first constant current path and the second constant current path to the base voltage source. The resistor is inserted in the third constant current path to produce the reference voltage, and the switching device is controlled so as to be turned-off when the output voltage of the comparator is a high voltage and turned-on when the output voltage of the comparator is a low voltage.

According to the above-described constitution, the value of the reference voltage produced by the resistor is proportional to the value of the current in the third current path, i.e. the sum of the value of the current flowing in the first current path and the value of the current flowing in the second current path. Moreover, when the output of the comparator is Hi, the switching device inserted in the second constant current path is made to be OFF to cause no current from the second constant current path to flow in the third constant current path. Thus, the reference voltage produced across the resistor inserted in the third constant current path is lowered. At this time, in the comparator, the threshold voltage at which the output voltage is switched to Low is also lowered together with the lowered reference voltage. Hence, the comparator keeps the output at Hi.

Conversely, when the output of the comparator is Low, the switching device inserted in the second constant current path is made to be ON to make the respective currents flowing in the first constant current path and the second constant current path join together to flow in the third constant current path. Thus, the reference voltage produced across the resistor inserted in the third constant current path is increased. At this time, in the comparator, the threshold voltage at which the output voltage is switched to Hi is also increased together with the increased reference voltage. Hence, the comparator keeps the output at Low. Therefore, according to the input decision circuit with the above-described features, a hysteresis characteristic is provided in an input to output relation, by which a stable output signal can be obtained.

In a third form of the invention, in the input decision circuit according to the second form of the invention, the comparator is formed with a MOSFET used for the switching device and the gate of the MOSFET is connected to the output terminal of the comparator so that the output voltage of the comparator is applied to the gate, by which an input decision circuit can be provided which is capable of making a more exact decision on the level of an input voltage.

Moreover, in a fourth form of the invention, in the input decision circuit according to any one of the first to the third forms, a base voltage source for driving the comparator that acts as a base of a voltage for driving the comparator is provided independently of the base voltage source that acts as the base common to the reference voltage and the input voltage. According to the foregoing constitution, the reference voltage and the input voltage are based only on the base voltage source common to them. Therefore, even in the case in which the driving voltage of the comparator or the electric potential of the base voltage source for driving the comparator is varied, with the reference voltage and the input voltage based only on the base voltage source common to them, the potential difference between them is kept constant. Moreover, the threshold voltage that is the reference of the switching operation of the comparator is based on a constant reference voltage, by which the possibility of shifting the threshold voltage is low.

Thus, the input decision circuit makes the threshold voltage hard to shift both onto the ON side and onto the OFF side even in the case when a potential difference is produced between the base voltage source common to the reference voltage and the input voltage and the base voltage source for driving the comparator. As a result, the input decision circuit is capable of carrying out a decision on the level of the input voltage by the more exact threshold voltage.

Here, the driving voltage of the comparator is based on the base voltage source for driving the comparator. Thus, when the driving voltage is varied, the electric potential of the base voltage source common to the reference voltage and the input voltage and the electric potential of the base voltage source for driving the comparator deviate from each other. Also in this case, the threshold voltage that is the operating reference becomes hard to shift. Namely, even in the case when the driving voltage of the comparator or the electric potential of the base voltage source for driving the comparator is varied, the threshold voltages become hard to shift both on the ON side and on the OFF side.

According to the invention, even in the case of the occurrence of any one of an electric potential variation in the base voltage source with respect to the reference voltage, an electric potential variation in the base voltage source with respect to an input voltage, a variation in the driving voltage of the comparator and an electric potential variation in the base voltage source for driving the comparator, the threshold voltages become hard to shift, by which an input decision circuit can be provided which is capable of carrying out more exact decision on the level of an input voltage.

### BRIEF DESCRIPTION OF THE DRAWINGS

FIG. 1 is a circuit diagram schematically showing an input decision circuit according to a first embodiment of the invention having a plurality of grounds and a p-channel MOSFET (Metal Oxide Semiconductor Field Effect Transistor);

FIGS. 2A and 2B are waveform diagrams showing relations among the reference voltages, an input voltage and an output voltage in the input decision circuit according to the first embodiment of the invention;

FIG. 3 is a graph illustrating that the threshold voltage on the ON side becomes independent of the voltage between the ground 1 and the ground 2 in the input decision circuit according to the first embodiment of the invention by comparison with the threshold voltage in the related input decision circuit;

FIG. 4 is a graph illustrating that the threshold voltage on the OFF side becomes independent of the voltage between the ground 1 and the ground 2 in the input decision circuit according to the first embodiment of the invention in comparison with the threshold voltage in the related input decision circuit;

FIG. 5 is a circuit diagram schematically showing an input decision circuit according to a second embodiment of the invention formed with a single ground;

FIG. 6 is a circuit diagram schematically showing an input decision circuit according to a third embodiment of the invention having a plurality of grounds and an n-channel MOSFET;

FIG. 7 is a circuit diagram schematically showing a related input decision circuit having a plurality of grounds; and

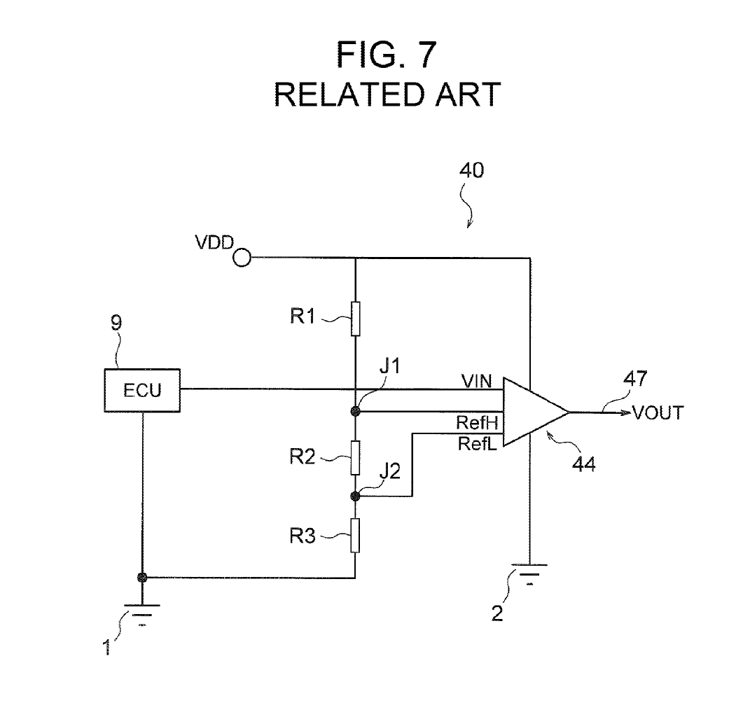

FIGS. 8A and 8B are waveform diagrams showing relations among the reference voltages, an input voltage and an output voltage in the related input decision circuit, with FIG. 8A showing the case in which the electric potential at the ground 1 is equal to the electric potential at the ground 2 and FIG. 8B showing the case in which the electric potential at the ground 1 is higher than the electric potential at the ground 2.

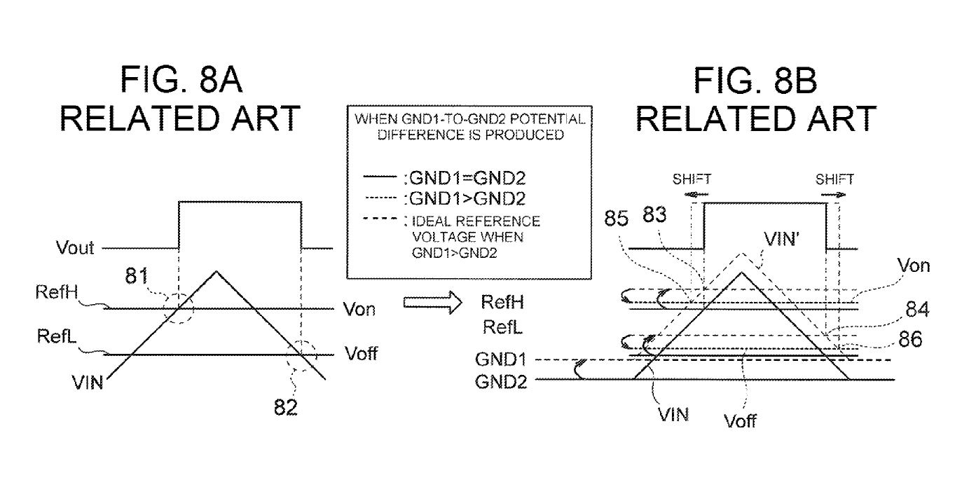

### DETAILED DESCRIPTION

### First Embodiment

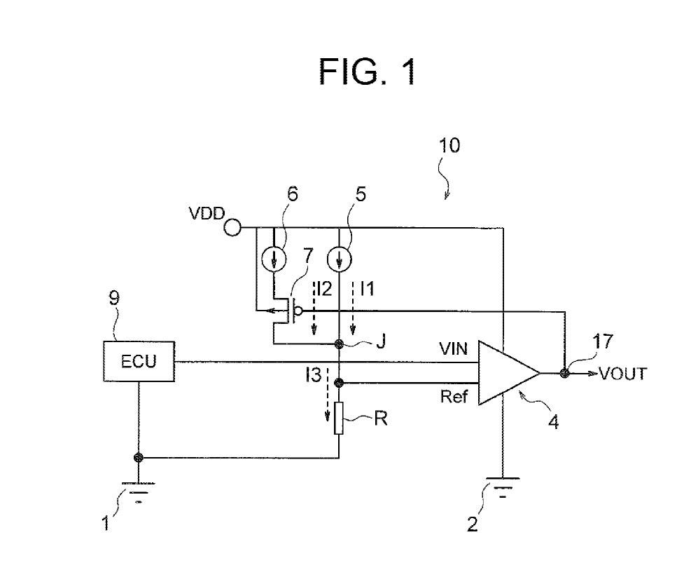

FIG. 1 is a circuit diagram schematically showing an input decision circuit according to a first embodiment of the invention having a plurality of grounds and a p-channel MOSFET. In the following, the first embodiment of the invention will be explained on the basis of FIG. 1. An input decision circuit 10 shown in FIG. 1 comprises a power supply VDD (DC power supply), a comparator 4, a base voltage source 1 (hereinafter also referred to as a ground 1 or a GND 1) to be the base common to a reference voltage Ref of the comparator 4 and an input voltage VIN, a base voltage source 2 (hereinafter also referred to as a ground 2 or a GND 2) of the comparator 4 provided independently of the ground 1, a first constant current source 5 (hereinafter simply referred to as a constant current source 5) forming a first constant current path, a second constant current source 6 (hereinafter simply referred to as a constant current source 6) forming a second constant current path, a switching device inserted in the second constant current path, e.g. a p-channel MOS type FET 7 (hereinafter simply referred to as a FET 7), a third constant current path from a joining point J of the first constant current path and the second constant current path to the ground 1, a resistor R inserted in the third constant current path to generate the reference voltage Ref, and an ECU 9 generating a signal subjected to a decision. Thus, the joining point J becomes a connection point J to the resistor R.

Between the power supply VDD and the ground 1, a reference voltage producing function producing the reference voltage Ref is inserted. The reference voltage producing function includes the constant current source 5 and the resistor R which are connected in series. The constant current source 5 is connected to the power supply VDD to make a constant current I1 flow in the reference voltage producing function. The resistor R is connected to the ground 1. Thus, a voltage produced across the resistor R with the ground 1 as a base is provided as the reference voltage Ref. Furthermore, the reference voltage producing function includes a constant current source having an ON/OFF control function additionally provided, which will be explained in the following.

The constant current source having the ON/OFF control function includes the constant current source 6 and the FET 7 which are connected in series. The constant current source 6 is connected to the power supply VDD to make the constant current I2 flow. The constant current source having an ON/OFF control function is connected in parallel to the constant current source 5. A path from the power supply VDD to the connection point J to the resistor R through the constant current source 6, the source of the FET 7 and the drain of the FET 7 is the path through which the constant current I2 flows.

At the connection point J to the resistor R, the constant current I1 from the constant current source 5 joins the constant current I2. Thus, with the FET 7 being ON, a constant current I3 as the sum of the constant current I1 and the constant current I2 flows in the resistor R. The gate of the FET 7 is connected to an output terminal 17 of the comparator 4. The FET 7 is controlled so as to be OFF when an output voltage VOUT at the output terminal 17 (hereinafter simply referred to as an output VOUT 17) of the comparator 4 is Hi and so as to be ON when the output VOUT 17 of the comparator 4 is Low.

Here, the constant current source 5 according to the first embodiment also corresponds to a constant current path according to the invention. Moreover, the constant current source having an ON/OFF control function according to the first embodiment, namely the path with the constant current source 6 and the FET 7 connected in series through which path the constant current I2 flows, corresponds to a second constant current path according to the invention. In addition, the resistor R according to the first embodiment through which the constant current I3 flows also corresponds to a third constant current path according to the invention. Furthermore, the joining point J of the first constant current path and the second constant current path is the same point as the connection point J to the resistor R, which corresponds to the joining point J according to the invention.

In the resistor R, the constant current I3 flows. The value of the constant current I3 is, as is expressed by the following expressions (1) and (2), the value of the constant current I1 when the FET 7 is OFF. When the FET 7 is ON, the value of the constant current I3 becomes a value in which the value of the constant current I2 is added to the value of the constant current I1. This produces the two reference voltages RefH and RefL as are expressed by the following expressions (1) and (2):

Reference voltage RefH for ON=(constant current I1+constant current I2)×resistance value of the resistor R=threshold voltage Von (1)

Reference voltage RefL for OFF=constant current I1×resistance value of the resistor R=threshold voltage Voff (2)

By adjusting the current values of the constant current I1 and the constant current I2, it becomes possible to adjust the threshold voltages Von and Voff and a hysteresis width. The largely set difference between the two reference voltages RefH and RefL widens a hysteresis width. Moreover, by the voltage values of the reference voltages RefH and RefL, the threshold voltages Von and Voff can be determined.

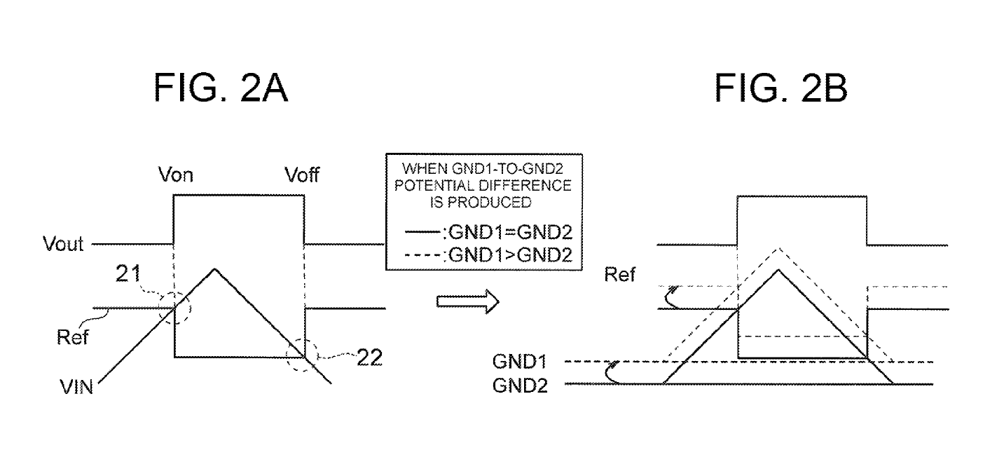

FIGS. 2A and 2B are waveform diagrams showing relations among the reference voltages, an input voltage and an output voltage in the input decision circuit according to the first embodiment of the invention. As is shown at operating points 21 and 22 in FIG. 2A, when the electric potential of the ground 1 and the electric potential of the ground 2 are equal to each other, the comparator 4 carries out a satisfactory input signal decision operation.

In FIGS. 2A and 2B, a state is also shown in which the reference voltage Ref is varied to the two threshold voltages Von and Voff of high and low expressed by the foregoing expressions (1) and (2), respectively, at the appropriate times. Namely, when the output VOUT 17 is Low, the reference voltage RefH for ON is determined at the slightly higher threshold voltage Von. Conversely, when the output VOUT 17 is Hi, the reference voltage RefL for OFF is determined at the slightly lower threshold voltage Voff.

In FIG. 2B, the case is shown when the electric potential of the ground 1 is higher than the electric potential of the ground 2 (hereinafter simplified as ground 1>ground 2). Also in this case, the reference voltage Ref obtained as a voltage across the resistor R inserted in the constant current path to the ground 1 is constant with respect to the ground 1. The reason is that the reference voltage Ref produced by the resistor R is constant, because it is determined as a product of the resistance value of the resistor R and the value of the constant current I3 flowing in the resistor R. Namely, the reference voltage Ref is either proportional to the constant current I1 made to flow only by the constant current source 5 or proportional to the sum of the constant current I1 and the constant current I2 made to flow by the constant current source 6. Moreover, the reference voltage Ref and the input voltage VIN use the ground 1, common thereto, as the base. Therefore, even in the case of ground 1>ground 2, the case of ground 1<ground 2 or the case when the voltage of the power supply VDD driving the comparator 4 is varied, the input voltage VIN and the reference voltage Ref are kept at their respective value with the same ground 1 determined as their base. Namely, the potential difference between the input voltage VIN and the reference voltage Ref is hard to change.

In addition, since the threshold voltages Von and Voff acting as the operating references of the comparator 4 are, as are expressed by the foregoing expressions (1) and (2), determined on the basis of the reference voltages RefH at a constant high level and the reference voltage RefL at a constant low level, respectively, no deviations from the determined values occur in the threshold voltages Von and Voff. As a result, the input decision circuit 10 is capable of making a more exact decision on the level of an input voltage VIN.

The reference voltage Ref produced across the resistor R is determined by the product of the resistance value of the resistor R and the value of the constant current I3 flowing in the resistor R, so that it is constant. Namely, the reference voltage Ref is either proportional to the constant current I1 made to flow by the constant current source 5 or proportional to the sum of the constant current I1 and the constant current I3 made to flow by the constant current source 6. Moreover, the FET 7 connected in series to the constant current source 6, being made to be OFF when the output VOUT 17 of the comparator 4 is Hi, causes no current by the constant current source 6 to flow in the resistor R at that time. Thus, the reference voltage RefL produced across the resistor R is lowered. At this time, the comparator 4 has the threshold voltage Voff, which switches an output to Low, lowered as is determined by the lowered reference voltage RefL. Therefore, the comparator 4 keeps the output at Hi.

Conversely, when the output VOUT 17 of the comparator 4 is Low, the FET 7 connected in series to the constant current source 6 is made to be ON. This allows the current as the sum of the constant current I1 from the constant current source 5 and the constant current I2 from the constant current source 6 to flow in the resistor R. Thus, the reference voltage RefH produced across the resistor R is increased. At this time, the comparator 4 has the threshold voltage Von, which switches an output to Hi, increased as is determined by the increased reference voltage RefH. Therefore, the comparator 4 keeps the output at Low. In this way, the comparator 4 has a hysteresis in the decision levels thereof to therefore make the operation stable.

The value of the reference voltage Ref, produced across the resistor R by the constant current I3 as the sum of the always flowing constant current I1 and the constant current I2 flowing at the appropriate times, is a constant value as a product of the value of the constant current I3 and the resistance value of the resistor R. The reference voltage Ref, even though the electric potential of the power supply VDD or the ground 1 is varied, is constant by the function of the constant current I3. In addition, the reference voltage Ref, being produced with only the electric potential of the ground 1 as a base, is independent of the electric potential of the ground 2. Moreover, the input voltage VIN is produced with only the electric potential of the ground 1 as a base, to be independent of the electric potential of the ground 2. Therefore, the potential difference between the reference voltage Ref and the input voltage VIN is hard to change even though the electric potential of the ground 1 is not equal to the electric potential of the ground 2.

Moreover, when a rail-to-rail input is used for expanding the common mode input voltage range of the comparator 4, the comparator 4 becomes operable to the potential difference ranging from the voltage of the power supply VDD to the voltage of the ground 1. The term “rail-to-rail input” means that the range of an allowable input voltage includes a power supply voltage.

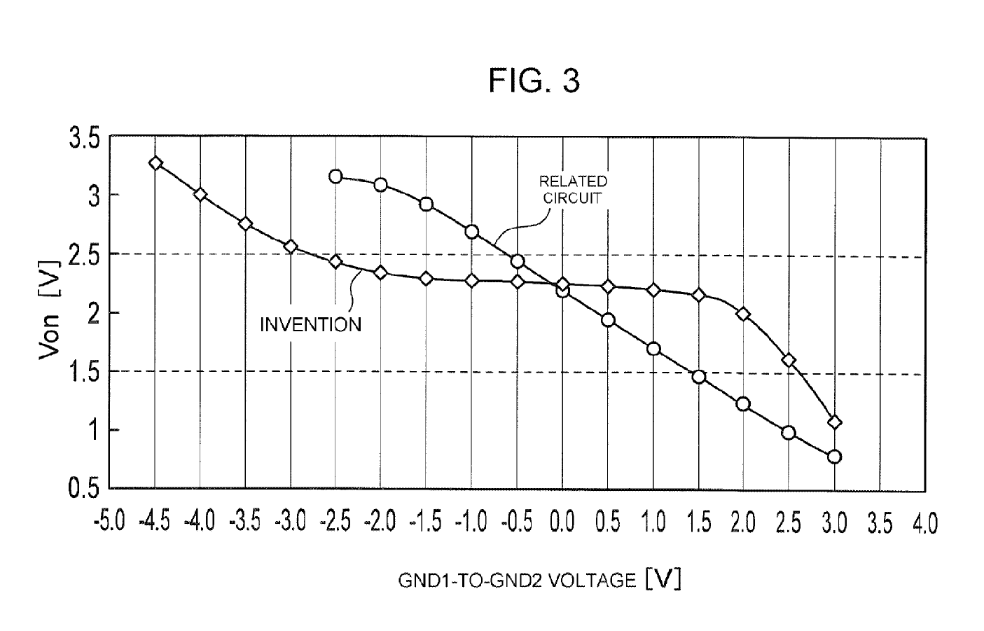

FIG. 3 is a graph illustrating that the threshold voltage on the ON side becomes independent of the voltage between the ground 1 and the ground 2 in the input decision circuit according to the first embodiment of the invention by comparison with the threshold voltage in the related input decision circuit. As is shown in FIG. 3, in the related input decision circuit 40, the threshold voltage Von on the ON side is considerably varied depending on the voltage between the ground 1 and the ground 2. Namely, as the electric potential of the ground 1 becomes higher than the electric potential of the ground 2, the threshold voltage Von on the ON side decreases. This causes the output VOUT 17 of the comparator 4 to become liable to be switched by a lower input voltage VIN from Low to Hi, i.e. to the ON signal. Compared with this, in the input decision circuit 10 according to the first embodiment, a remarkable advantage is obtained in which the threshold voltage Von exhibits little variation in a certain range.

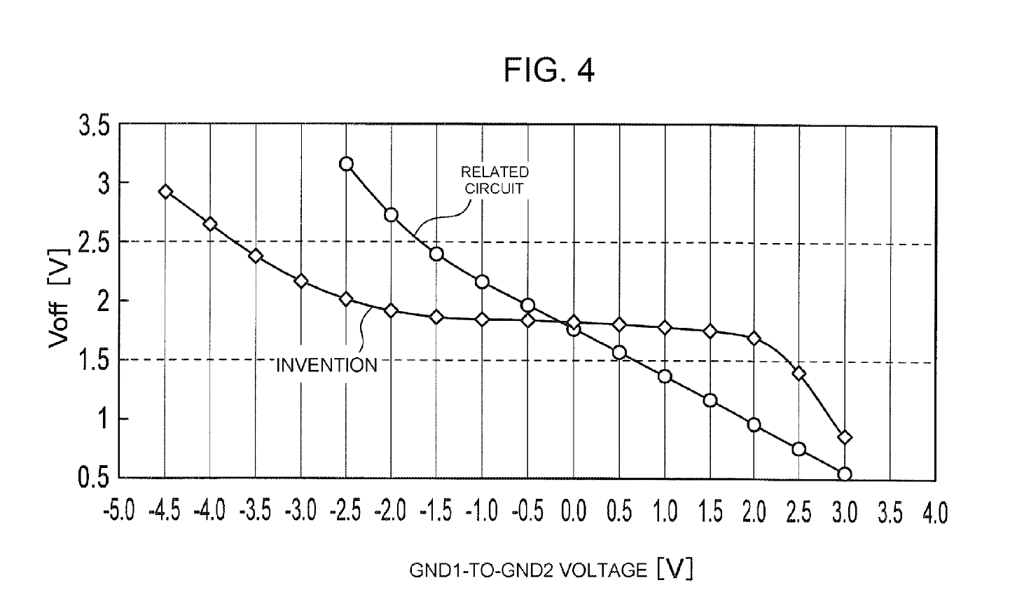

FIG. 4 is a graph illustrating that the threshold voltage on the OFF side becomes independent of the voltage between the ground 1 and the ground 2 in the input decision circuit according to the first embodiment of the invention in comparison with the threshold voltage in the related input decision circuit. As is shown in FIG. 4, in the related input decision circuit 40, the threshold voltage Voff on the OFF side is considerably varied depending on the voltage between the ground 1 and the ground 2. Namely, as the electric potential of the ground 1 becomes higher than the electric potential of the ground 2, the threshold voltage Voff on the OFF side decreases. This causes the output VOUT 17 of the comparator 4 to become liable to be switched by a lower input voltage VIN from Hi to Low, i.e. to the OFF signal. Compared with this, in the input decision circuit 10 according to the first embodiment, a remarkable advantage is obtained in which the threshold voltage Voff exhibits little variation in a certain range.

### Second Embodiment

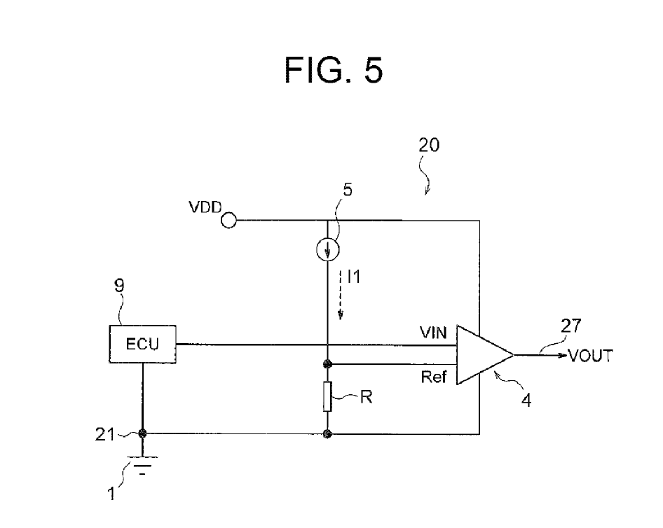

FIG. 5 is a circuit diagram schematically showing an input decision circuit according to the second embodiment of the invention formed with a single ground. An input decision circuit 20 shown in FIG. 5 includes a power supply VDD, aground 21, a constant current source 5, a resistor R, an ECU 9 and a comparator 4. The comparator 4 has an output terminal 27 outputting an output VOUT. The comparator 4 according to the second embodiment of the invention is also explained as a hysteresis comparator. However, there is no necessity of limiting the comparator 4 to a hysteresis comparator.

Between the power supply VDD and the ground 21, the constant current source 5 making a constant current I1 flow and the resistor R are connected in series. Across the resistor R, a constant reference voltage Ref is produced the value of which voltage is determined by the product of the value of the constant current I1 and the resistance value of the resistor R. In this way, even with the input decision circuit 20 formed with the single ground 21, the unvaried reference voltage Ref is produced by the resistor R connected to the constant current source 5.

In the input decision circuit 20, the constant reference voltage Ref and an input voltage VIN are given with the electric potential of the ground 21 common thereto as the base. Therefore, even in the case when the electric potential of the ground 21 or the voltage of the power supply VDD for driving the comparator 4 is varied, the values of the input voltage VIN and the reference voltage Ref are kept at their respective values with the electric potential of the same ground 21 determined as the base.

Namely, there is no change in the potential difference between the input voltage VIN and the reference voltage Ref. Moreover, the threshold voltages Von and Voff acting as the operating references of the comparator 4, being determined on the basis of the reference voltages Ref, cause shifts in neither the threshold voltage Von on the ON side nor the threshold voltage Voff on the OFF side. As a result, the input decision circuit 20 is capable of making a more exact decision on the level of an input voltage with respect to the threshold voltages Von and Voff even in the case when the electric potential of the ground 21 or the voltage of the power supply VDD for driving the comparator 4 is varied.

Here, the description “Between the power supply VDD and the ground 21, the constant current source 5 making a constant current I1 flow and the resistor R are connected in series.” according to the second embodiment corresponds to the description “including a constant current source that supplies a constant current to a constant current path formed between a DC power supply and the base voltage source, and a resistor inserted in the constant current path,” according to the invention. Moreover, the description “the constant reference voltage Ref and an input voltage VIN are presented with the ground 21 common thereto as the base,” according to the second embodiment corresponds to the description “a base voltage source that acts as a base common to the reference voltage and the input voltage” according to the invention. Furthermore, the description “the constant current source 5 making a constant current I1 flow and the resistor R are connected in series. Across the resistor R, a constant reference voltage Ref is produced the value of which voltage is determined by the product of the value of the constant current I1 and the resistance value of the resistor R.” according to the second embodiment corresponds to the description “with the electric potential of the base voltage source as a base, a constant voltage produced across the resistor acts as the reference voltage” according to the invention.

### Third Embodiment

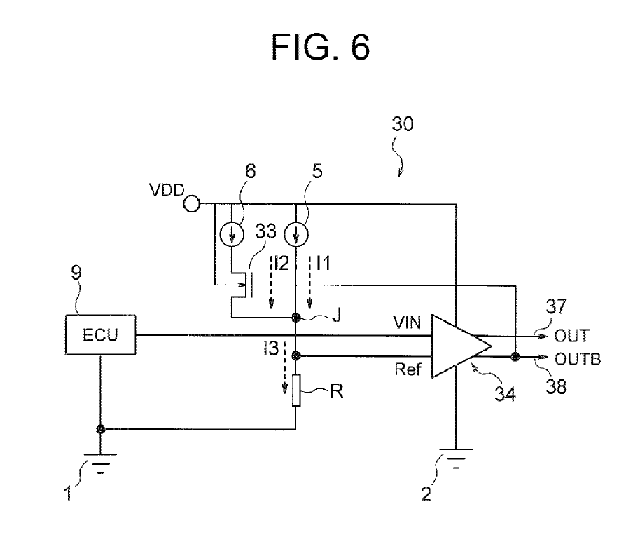

FIG. 6 is a circuit diagram schematically showing an input decision circuit according to a third embodiment of the invention having a plurality of grounds and an n-channel MOSFET. The input decision circuit 30 shown in FIG. 6 includes a power supply VDD, a ground 1, a ground 2, a constant current source 5, a constant current source 6, an n-channel MOS FET 33 (hereinafter simply referred to as a FET 33), a resistor R, an ECU 9 and a comparator 34. The comparator 34 has an output terminal 37 outputting an output OUT and an output terminal 38 outputting an output OUTB the phase of which is the reverse of the phase of the output OUT of the output terminal 37

In the input decision circuit 30, between the power supply VDD and the ground 1, the constant current source 5 making a constant current I1 flow as a first constant current path and the resistor R are connected in series. Moreover, with the constant current source 5 making a constant current I2 flow and the FET 33 connected in series, a second constant current path is formed. The second constant current path is connected in parallel to the constant current source 5 as the first constant current path. Namely, the path from the power supply VDD to the connection point J to the resistor R through the constant current source 6, the drain and the source of the FET 33 is the second constant current path in which a constant current I2 flows. To the connection point J to the resistor R, the first constant current path and the second constant current path are joined. Thus, in a third constant current path as a path from the connection point J to the ground 1, i.e. the resistor R, a constant current I3 as a sum of the constant current I1 and the constant current I2 can be made to flow. The gate of the FET 33 is connected to the output terminal 38 of the comparator 34.

The difference between the input decision circuit 30 shown in FIG. 6 and the input decision circuit 10 shown in FIG. 1 is that the polarity of the voltage applied to the gate of the FET 33 being used is determined in reverse to the polarity of the voltage applied to the gate of the FET 7 in the input decision circuit 10 because of the difference between the p-channel and the n-channel. Specifically, the gate of the FET 33 is connected to the output terminal 38 of the comparator 34. In the comparator 34, because the phase of the output OUT 38 and the phase of the output OUT 39 are the reverse of each other, when the level of the output OUT 37 is Hi and the level of the output OUTB 38 is Low, the FET 33 is brought to be OFF. Conversely, when the level of the output OUT 37 is Low and the level of the output OUTB 38 is Hi, the FET 33 is brought to be ON.

Here, the description “with the constant current source 5 making a constant current I2 flow and the FET 33 connected in series,” according to the third embodiment corresponds to the description “a switching device inserted in the second constant current path” according to the invention. Moreover, “the path from the power supply VDD to the connection point J to the resistor R through the constant current source 6, the drain and the source of the FET 33” according to the third embodiment corresponds to “a second constant current path” according to the invention.

The following explanation overlaps the explanation of the first embodiment. The explanation “To the connection point J to the resistor R, the first constant current path and the second constant current path are joined. Thus, in a third constant current path as a path from the connection point J to the ground 1, i.e. the resistor R, a constant current I3 as a sum of the constant current I1 and the constant current I2 can be made to flow” corresponds to the description “includes a second constant current source that makes a constant current flow in a second constant current path, a switching device inserted in the second constant current path, and a third constant current path from the joining point of the first constant current path and the second constant current path to the base voltage source, in which the resistor is inserted in the third constant current path to produce the reference voltage,” according to the invention.

The input decision circuit 30 has the constant current source 5 in which the constant current I1 flows and the constant current source 6 in which the constant current I2 flows to carry out ON/OFF control of the constant current source 6 as one of the constant current sources, by which the two reference voltages RefH and RefL expressed by the foregoing expressions (1) and (2) are produced. Moreover, by adjusting the current values of the constant current I1 and the constant current I2, it becomes possible to adjust threshold voltages Von and Voff and a hysteresis width. The operation/working-effect is the same as that of the input decision circuit 10 explained with reference to FIG. 1.

In the resistor R, the constant current I3 flows. The value of the constant current I3 is, as is expressed by the foregoing expressions (1) and (2), the value of the constant current I1 when the FET 33 is OFF. When the FET 33 is ON, the value of the constant current I3 becomes a value in which the value of the ON/OFF controlled constant current I2 is added to the value of the constant current I1 at the appropriate times as is expressed by the expression (1). This produces the two reference voltages RefH and RefL as are expressed by the foregoing expressions (1) and (2).

As was explained in the foregoing, according to the first to third embodiments of the invention, even in the case of the occurrence of any one of an electric potential variation in the base voltage source with respect to the reference voltage, an electric potential variation in the base voltage source with respect to an input voltage, a variation in the driving voltage of the comparator and an electric potential variation in the base voltage source for driving the comparator, the threshold voltages becomes hard to shift, by which an input decision circuit can be provided which is capable of carrying out more exact decision on the level of an input voltage.

Any one of the input decision circuits according to the embodiments of the invention is preferably used for a device such as an igniter of an automobile engine in which electric potentials of generally provided grounds are not necessarily uniform. In such a case, a battery is used as a power supply VDD for driving a comparator on condition that the power supply voltage fluctuates and one end of the battery is conductively joined to a metal body as one ground and, along with this, is also conductively joined to an engine as the other ground.

While the present invention has been particularly shown and described with reference to the preferred embodiments thereof, it will be understood by those skilled in the art that the foregoing and other changes in form and details can be made therein without departing from the spirit and scope of the present invention.

What is claimed is:

1. An input decision circuit, comprising:
a comparator that outputs one of a high voltage or a low voltage on the basis of a result of a comparison between a reference voltage and an input voltage;
a base voltage source that acts as a base common to the reference voltage and the input voltage;
a constant current source that supplies a constant current to a constant current path formed between a DC power supply and the base voltage source; and
a resistor inserted in the constant current path, wherein with an electric potential of the base voltage source as a base, a constant voltage produced across the resistor acts as the reference voltage.

2. The input decision circuit of claim 1, wherein the input decision circuit further comprises:
a first constant current source that makes a constant current flow in a first constant current path;
a second constant current source that makes a constant current flow in a second constant current path;
a switching device inserted in the second constant current path; and
a third constant current path from a joining point of the first constant current path and the second constant current path to the base voltage source,
wherein
the resistor is inserted in the third constant current path to produce the reference voltage, and
the switching device is turned off when the output voltage of the comparator is a high voltage and turned on when the output voltage of the comparator is a low voltage.

3. The input decision circuit of claim 2, wherein the switching device includes a MOSFET and a gate of the MOSFET is connected to an output terminal of the comparator so that the output voltage of the comparator is applied thereto.

4. The input decision circuit of claim 1, wherein a base voltage source for driving the comparator that acts as a base of a voltage for driving the comparator is provided independently of the base voltage source that acts as the base common to the reference voltage and the input voltage.

5. The input decision circuit of claim 2, wherein a base voltage source for driving the comparator that acts as a base of a voltage for driving the comparator is provided independently of the base voltage source that acts as the base common to the reference voltage and the input voltage.

6. The input decision circuit of claim 3, wherein a base voltage source for driving the comparator that acts as a base of a voltage for driving the comparator is provided independently of the base voltage source that acts as the base common to the reference voltage and the input voltage.

7. A device, comprising:
a comparator configured to perform a comparison of an input voltage to a reference voltage and output a binary-valued decision voltage based on the comparison; and
a resistor;
wherein a constant current flowing through the resistor is to supply the reference voltage, with the input voltage and the resistor coupled to a common electric potential.

8. The device of claim 7, further comprising:
at least one constant current source coupled to a terminal of the resistor, and configured to supply the constant current.

9. The device of claim 8, wherein the at least one constant current source comprises a first constant current source and a second constant current source, and a switching device is coupled between the first constant current source and the terminal of the resistor.

10. The device of claim 9, wherein the output of the comparator is coupled to the switching device.

11. The device of claim 10, wherein the comparator is configured to be coupled to an electric potential independent of the common electric potential of the input voltage and the resistor.
